(19) United States
(12) Patent Application Publication
(10) Pub. No.: US 2013/0240025 A1
(43) Pub. Date: Sep. 19, 2013

(54) BUOYANT SOLAR PANEL, AND SOLAR POWER PLANT CONSISTING OF AN ASSEMBLY OF SAID PANELS

(71) Applicants: Giacomo Bersano, Antony (FR); Massimo Bobbio, Torino (IT)

(72) Inventors: Giacomo Bersano, Antony (FR); Massimo Bobbio, Torino (IT)

(73) Assignee: ACTIVE INNOVATION MANAGEMENT, Antony (FR)

(21) Appl. No.: 13/990,497

(22) PCT Filed: Nov. 29, 2011
(86) PCT No.: PCT/FR2011/052806

§ 371 Date: May 30, 2013

(30) Foreign Application Priority Data
Nov. 30, 2010 (FR) 1059899

(51) Int. Cl. H01L 31/042

(52) U.S. Cl. CPC H01L 31/0422
USPC 136/251

(57) ABSTRACT

A solar panel is provided including a solar energy collector, such as solar collectors or photovoltaic cells, the panel also including a top surface. The solar panel includes a one-piece buoyant structure on which a solar energy collector is mounted, the collector being built into a solar module arranged on the buoyant structure, in particular in a flat manner. The panel has, in a direction perpendicular to the top surface, a substantially constant thickness within at least one peripheral region of the panel. The present panel can be used in the field of sea-based solar power plants or solar power plants in any other aquatic environment.

The invention relates to the field of solar panels and in particular solar panel power plants in an aquatic environment. By “solar panel” is meant generally in the following text a panel having conventional dimensions of the order of 1 to 3 m², that can be easily handled and transported, and capable of providing an output of the order of 1.3 kW/m²

Despite the current development of solar power, tight budgets for land (cost per m²) and technical requirements (construction, fixing etc.) place a severe restriction on development in some regions or some urban environments. Land-based power plants are not compatible with other uses of the land, for example agriculture. Moreover, solar power plants are sometimes criticized for their appearance, which can affect the aesthetics of a landscape or the external finish of a building supporting the panels.

The aquatic environment offers a very promising possibility for such solar panel installations, both in a marine environment and on lakes or rivers: the surface area cost is small and there is little or no human habitation. The concept of solar panels installed in an aquatic environment is already known. The existing devices use for example an artificial island several tens or even hundreds of metres wide or a buoyant support typically having sides or a diameter of several metres on which a large number of conventional solar panels are placed. This type of power plant is heavy, inconvenient to install and forms a screen that is detrimental to photosynthesis on the sea bed. Moreover, this type of power plant has a surface that is very exposed to birds alighting on the panels and to their faeces, which cause rapid deterioration and/or costly maintenance. Inasmuch as the power plant is less accessible than on land, the upkeep and maintenance are correspondingly more expensive.

The purpose of the present invention is to overcome all or some of the aforementioned drawbacks of the known solar panels and the corresponding power plants.

To this end, a subject of the invention is a solar panel comprising solar power collecting means, such as solar collectors or photovoltaic cells, an upper face, characterized by comprising a unitary buoyant structure on which the solar power collecting means are mounted, the latter being incorporated into a solar module arranged, in particular flat, on the buoyant structure, the panel having, in a direction perpendicular to the upper face, a substantially constant thickness at least in a peripheral region of the panel.

The solar panels are therefore buoyant independently of one another. Their buoyant structure is so named because it supports and carries the collecting means (it is in this sense “structural”). The compact design of the panels according to the invention makes them robust and easy to transport. The distribution of the buoyancy means below the upper face allows for excellent support and maximum stability of the panel when afloat. Moreover, they can withstand the weight of one or two persons to provide for maintenance operations.

According to further advantageous features of the invention, the solar power collecting means are constituted by photovoltaic cells.

According to yet further advantageous features of the invention, the buoyant structure is shaped to position the upper face substantially horizontally. The panel provides minimum windage and is less subject to overturning or destabilization resulting from a heavy swell. The stability of the panel on the surface of the water is significantly improved.

According to yet further advantageous features of the invention, the buoyant structure is adapted to position the upper face substantially flush with the level of the surrounding liquid, in particular seawater or fresh water. In this embodiment, the upper face of the panel is constantly wetted under the activity of the swell. Birds that do not like to have wet feet will not alight, or rarely, on the upper face of the panel, thus avoiding bird faeces and providing the panel with a long life time and minimum cleaning. The costs of cleaning and maintenance are considerably reduced, optimizing the economic operating conditions of such panels.

According to yet further advantageous features of the invention, viewed from above the solar panel has the general shape of a parallelogram, for example a rectangle or square. Its surface area is preferably less than 4 m², for example between 1 and 2 m². The panel typically, but non-limitatively, has dimensions of the order of 1.50 m-1.60 m by 0.90 m-1 m. Such a panel is very compact owing to its external dimensions. Its dimensions are similar to the conventional dimensions of a panel used on land, on the ground or mounted on a roof. Such panel can be transported easily and allows for easy installation. Moreover, in the event of malfunction, it can be replaced independently and singly, without affecting the other surrounding panels that are operating correctly.

According to yet further advantageous features of the invention, the buoyancy means are uniformly distributed below the upper face.

According to yet further advantageous features of the invention, the buoyancy means are distributed on the periphery of the upper face.

According to yet further advantageous features of the invention, the buoyant structure comprises a chassis in which are stacked, from bottom to top, at least one support plate, in particular made of fibreglass, at least one buoyant slab, in particular made of polymer, and a layer of solar power collecting means.

According to yet further advantageous features of the invention, the chassis comprises a frame the fibreglass sides of which are connected at the corners of the frame via brackets, in particular made from stainless metal.

According to yet further advantageous features of the invention, the chassis comprises a stainless metal structure having the general form of a frame.

According to yet further advantageous features of the invention, the solar panel comprises shock absorbing fenders situated on the periphery of the panel, these fenders being in particular buoyant and made from polyurethane.

According to yet further advantageous features of the invention, the solar panel comprises attachment means allowing several solar panels of the same type to be secured together.

According to yet further advantageous features of the invention, the solar panel comprises at least one watertight electrical connector allowing the photovoltaic cells to be electrically connected. Said connector is accessible and provides a high level of safety in use.

A subject of the invention is also a solar power plant comprising an assembly of several solar panels having all or some of the aforementioned features, the individually buoyant panels being juxtaposed forming a net, having in particular the general shape of a square or rectangle. Other shapes can of course be envisaged, for example circular or polygonal shapes. Although assembled together, each panel is independently buoyant in water. The power plant offers very easy installation and maintenance. As the panels as a whole are flush with the surface of the water, there is a low visual impact on the marine and coastal environment. The independent panels are able to move in relation to each other (by deformation of the cables, cords, straps or rigid rods connecting them together): the panels are able to adopt a more or less tilted position in relation to each other so as to be fully adapted to swell phenomena. The costs are optimized and offer a genuine alternative both to conventional power plants on land and to the known more complex or rigid marine power plants.

According to further advantageous features of the invention, the panels of the power plant are secured directly to each other by means of a system of cords, cables or straps connecting their chassis or their support plate or their shock absorbing fenders.

According to yet further advantageous features of the invention, the panels are secured on a common net of cables, cords or straps, by means of their chassis or support plate or their shock absorbing fenders.

According to yet further advantageous features of the invention, the power plant comprises peripheral retaining means situated around the set of solar panels so as to immobilize it with a substantially flat arrangement of the juxtaposed panels.

According to yet further advantageous features of the invention, the peripheral retaining means are constituted by several flotation buoys immobilized by a system of submerged weights, in particular four flotation buoys situated at the four corners of a set of solar panels having a generally square or rectangular shape.

According to yet further advantageous features of the invention, at least one peripheral retaining means incorporates in a particular embodiment a static converter for processing the electricity originating from the solar panels of the photovoltaic type by suitable conducting means, said converter conveying the electricity to an electricity network remote from the solar power plant.

The invention will be better understood on reading the following description of a non-limitative embodiment of the invention and in the light of the attached drawings, in which:

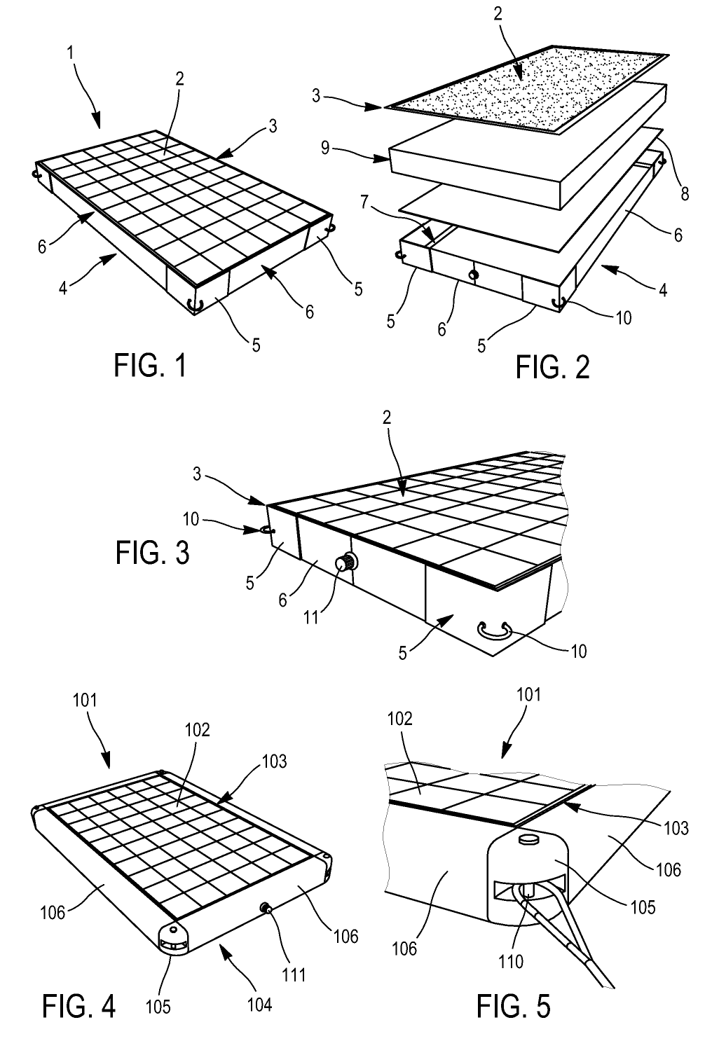

FIG. 1 represents a solar panel according to a first embodiment of the invention,

FIG. 2 represents an exploded perspective view of the solar panel in FIG. 1,

FIG. 3 is a perspective view of a detail of the construction of the panel in FIG. 1 showing the position of a watertight electrical connector,

FIG. 4 is a perspective view of a solar panel according to a further embodiment of the invention,

FIG. 5 shows a detail of the construction of the panel in FIG. 4, representing attachment means of the panel,

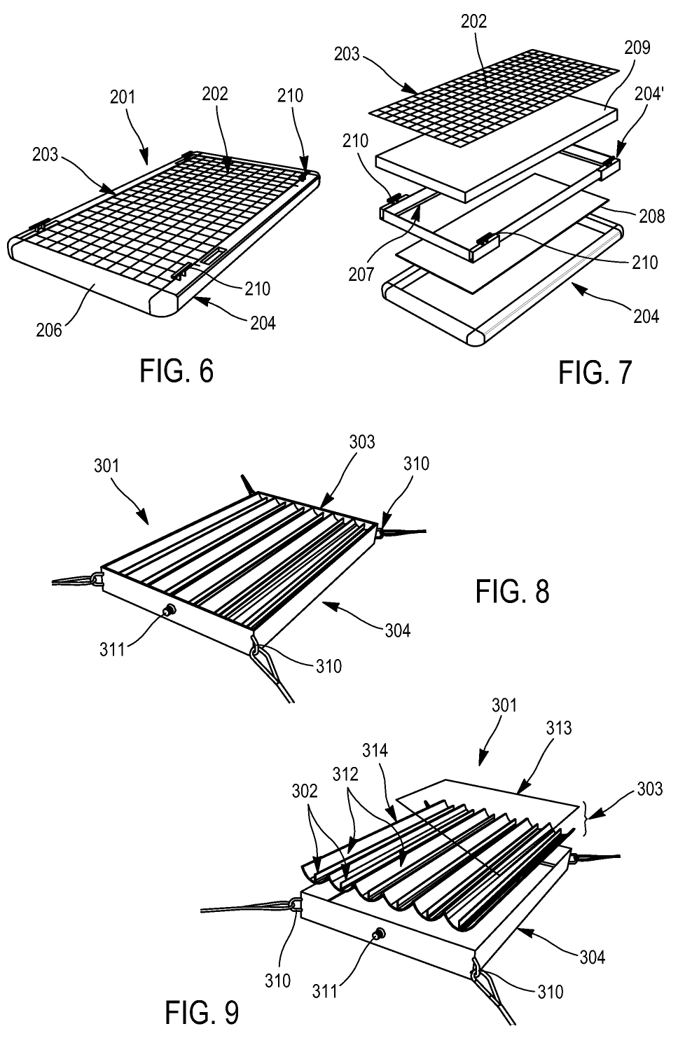

FIG. 6 represents a solar panel according to yet a further embodiment of the invention,

FIG. 7 is an exploded perspective view of the solar panel in FIG. 6.

FIG. 8 represents a solar panel according to yet a further embodiment of the invention, in which concentration means are provided, contributing in particular to the structural stability and stiffness of the panel,

FIG. 9 represents an exploded perspective view of the solar panel in FIG. 8,

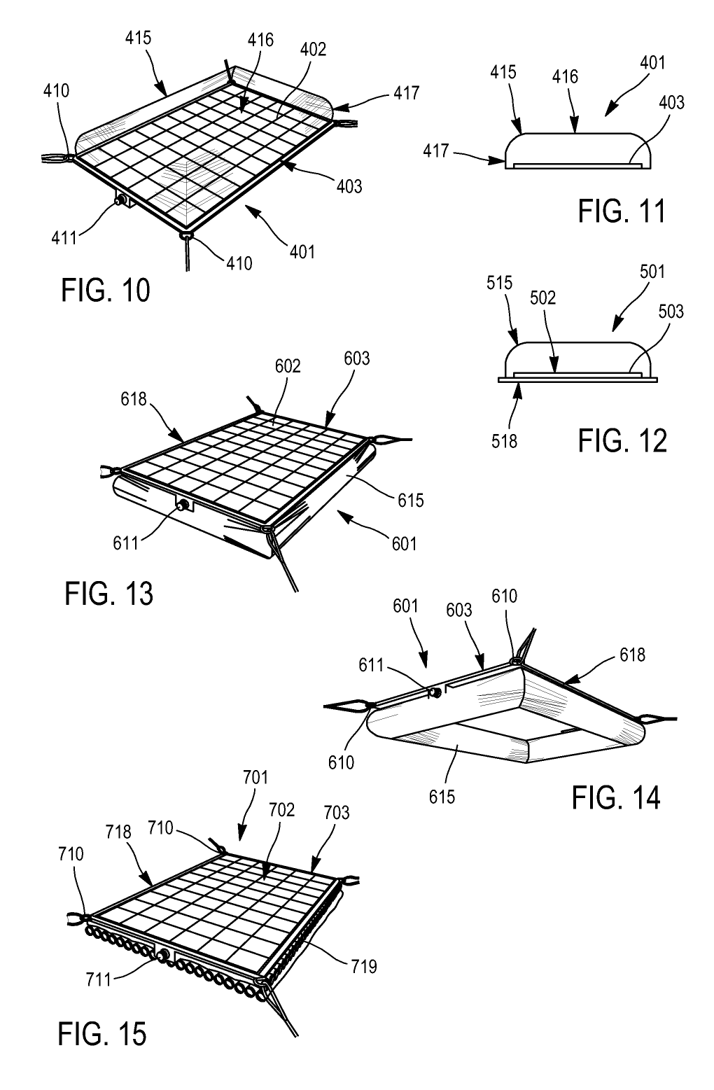

FIG. 10 represents yet a further embodiment of the solar panel according to the invention,

FIGS. 11 and 12 show two variant embodiments of the solar panel in FIG. 10, in which an inflatable structure is load-bearing or not,

FIGS. 13 and 14 represent two perspective views, top and bottom, of a solar panel according to a further embodiment of the invention, in which the buoyancy means are constituted by a peripheral inflatable sponson,

FIG. 15 represents yet a further embodiment of the invention in which the buoyancy means are constituted in this example by two superimposed layers of bamboo canes,

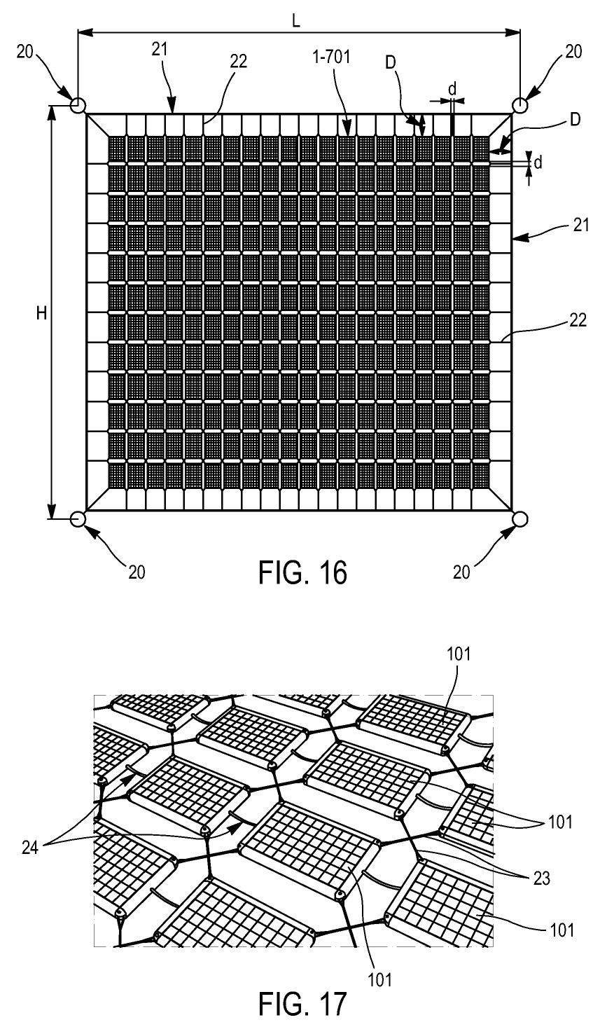

FIG. 16 represents in a top view, an example of a solar panel power plant according to the invention,

FIG. 17 shows an enlarged view of a detail of the assembly of solar panels according to the invention, in which the panels are directly connected to each other,

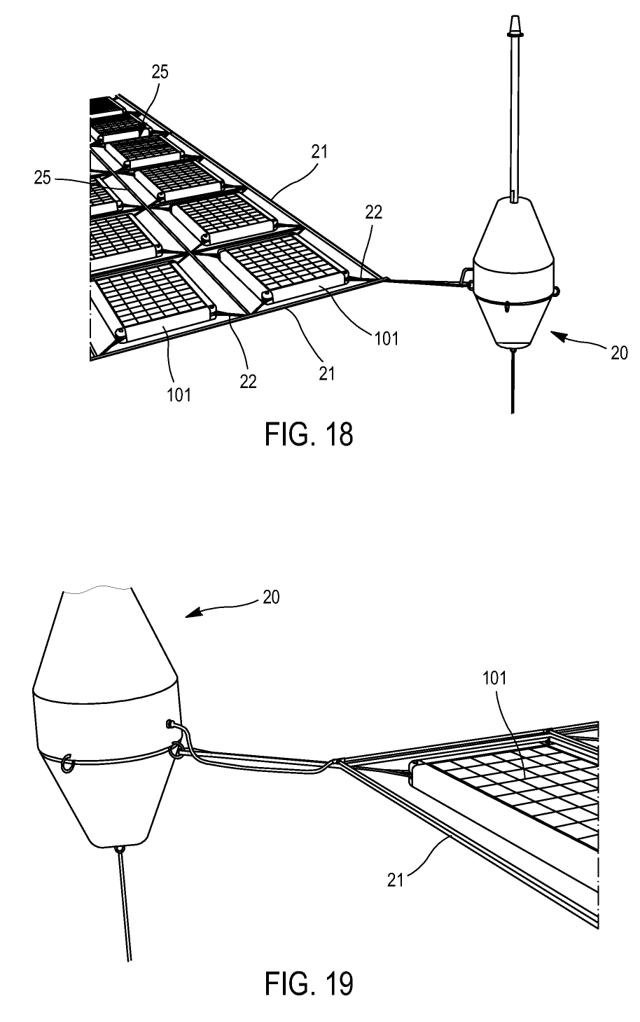

FIG. 18 shows retaining means situated on the periphery of the solar panel power plant according to the invention, said means typically being a flotation buoy,

FIG. 19 is an enlarged view of the buoy in FIG. 18, showing the mechanical connection means and the electrically conducting means reaching the buoy, into which a static converter is incorporated,

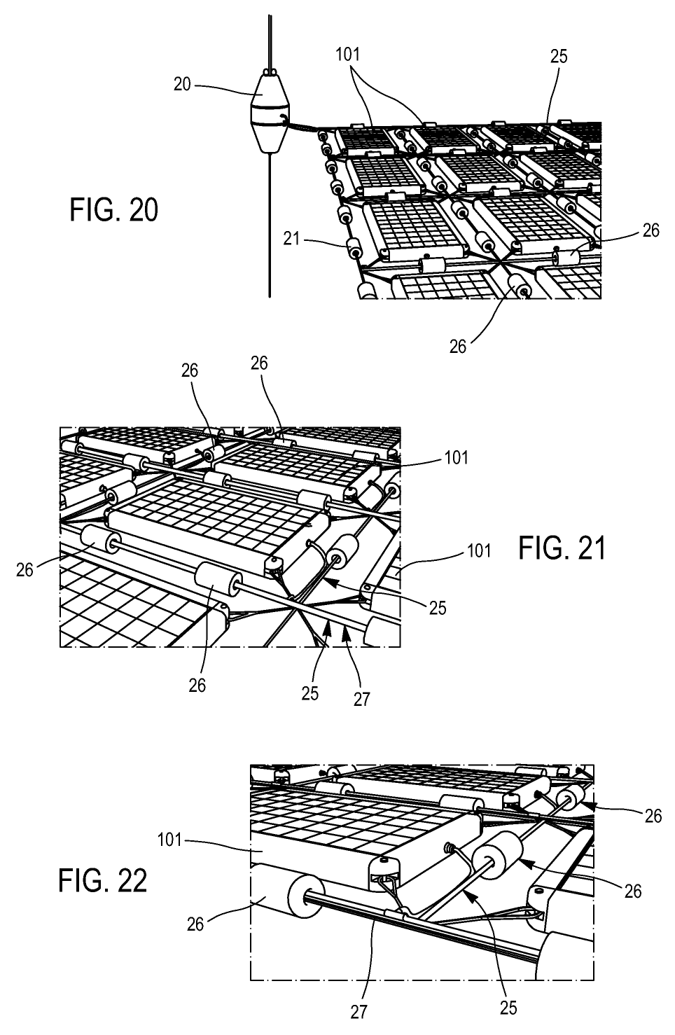

FIG. 20 is an enlarged view of the assembly of solar panels according to the invention, in which the panels are secured to a net of cables, cords or straps,

FIGS. 21 and 22 are enlarged views of the mechanical connection means of the assembly in FIG. 20 and the electrically conducting means connecting the panels to the buoy containing a static converter, and

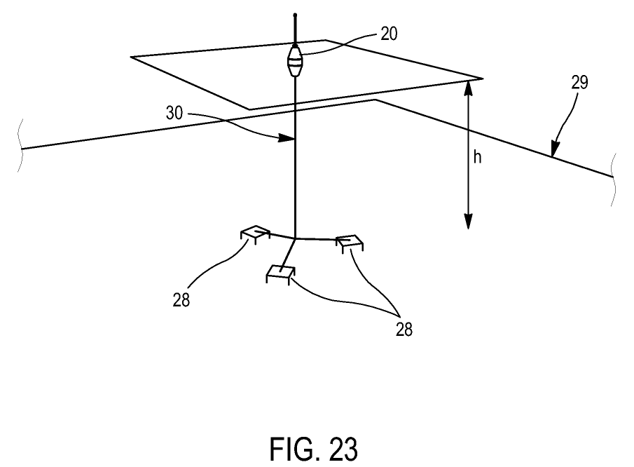

FIG. 23 is a perspective view of peripheral retaining means of the power plant, typically a retaining buoy, showing a system of submerged weights to which the retaining means are connected.

In the figures, the fine dash-dotted lines represent arbitrary limits of representation, although in reality the elements continue beyond said lines.

FIG. 1 represents a solar panel 1 according to the invention. The panel shown is typically a solar panel with photovoltaic cells 2 arranged on an upper face of the panel 1. The upper face denotes more specifically a face of the panel which is turned upwards and is exposed to solar radiation. In the example shown, said upper face comprises 60 solar cells of standard sizes 156 mm×156 mm, giving it dimensions of the order of 0.93 m×1.56 m. The solar panel of said example has a surface area of the order of 1.45 m², on the understanding that panels having other dimensions and a different number of cells are also included within the scope of the invention. It will be understood more generally that such a panel has a surface area of less than 4 m², in particular a cell surface area comprised between 1 and 2 m², the criterion being that such a panel should have standard dimensions and be sufficiently compact to allow easy transportation and installation by one or two persons. Conventionally, a solar panel with photovoltaic cells has an output comprised between 0.1 and 0.15 kW/m², for example 0.13 kW/m². A panel having the dimensions of the preceding example of 1.45 m² therefore provides an output of approximately 0.19 kW.

In order to protect the photovoltaic cells 2, the latter are typically grouped in a solar module 3 constituted by an upper protective layer made of perfectly transparent tempered glass that may be treated against mosses. The glass can moreover optionally be polarizing, as known to a person skilled in the art of solar photovoltaic modules. The module is also constituted by a lower layer covered with a special film. The photovoltaic cells 2 are inserted by encapsulation between the two layers in a watertight body

that is transparent and UV-resistant. The solar module is very resistant to mechanical stresses and to impacts. Within the scope of the invention, the solar module, which is referred to more simply and more generally as “photovoltaic cells”, is mounted in a watertight manner on a unitary buoyant carrying structure. The photovoltaic cells are arranged on an upper face, exposed to solar radiation, of the solar panel 1.

The buoyant structure is called “unitary” in the sense that it is constituted by elements assembled rigidly together in a compact manner, i.e. with no element or portion thereof projecting with respect to the general shape of the panel. As its name indicates, the panel has a generally flattened shape which in a top view is that of a quadrilateral, typically a rectangle having the aforementioned dimensions.

Remarkably, the panel 1 according to the invention has a substantially constant thickness in at least one peripheral region.

With reference to the embodiment in FIG. 2, the panel 1 comprises a chassis 4 having the general shape of a rectangular frame. The sides of the chassis 4 are arranged on the periphery of the panel 1. The height of the chassis 4 substantially determines the height of the panel. The chassis 4 comprises four corners 5 or metal brackets. These corners 5 are connected in twos by profiles 6 typically made of fibreglass, in order to form the short and long sides of the frame. The profiles have a lower rim 7 turned towards the centre of the panel 1, said rim constituting a retaining surface of the elements inserted in the chassis 4. Moving from bottom to top in FIG. 2, the stack within the chassis 4 consists of:
a support plate 8 forming a stiff base of the panel 1, for example made of fibreglass,
buoyancy means 9 constituted in this example by a buoyant slab for example made of polymer, the function of which is on the one hand to ensure the buoyancy of the panel on the surface of the water, but also to constitute a structural element contributing a high degree of stiffness to the panel (in particular opposing bending and twisting or warping of the panel).
a layer of photovoltaic cells 2 in the form of a solar module 3 as explained previously.

In this example, the panel is placed flat, substantially horizontally (theoretical position on the surface of calm water, in the absence of swell).

According to a particularly beneficial aspect of the invention, the buoyancy means 9 are included within the thickness of the panel, considered in a direction perpendicular to the upper face of the panel. In the example in FIGS. 1 and 2, these buoyancy means even represent almost the thickness of the panel 1, or at least more than 75% thereof. The buoyancy means are moreover in this example uniformly distributed in the form of a slab below the upper face of the panel 1. As will be stated subsequently, it is noted that an at least peripheral distribution of the buoyancy means in a peripheral region ensures suitable stability on the surface of the water.

The buoyant structure is adapted to position the upper face of the panel 1 in a manner that is substantially flush with the water level (theoretical position in calm water). To this end, the buoyancy properties of the buoyancy means 9 must be adapted to the overall weight of the solar panel 1, so as to compensate for the effect of gravity on the panel 1 by buoyancy and thus to place its upper face at the required level. This is particularly true in the first embodiment. It will become apparent subsequently that the panel 1 can be kept afloat by other means or with the assistance of other means, in which case this criterion may be less important.

In a variant embodiment (not shown) of the buoyancy means, the latter can be constituted by a cellular structure, for example in a honeycomb.

The solar panel in FIGS. 1 to 3 moreover comprises attachment means 10, constituted in the case in point by a stainless metal ring firmly fixed to each of the corners 5. These attachment means 10 make it possible to secure together several panels 1 of the same type or to make them fast

on a fixed point by means of a system of cables, cords or straps or even rigid rods/link rods.

The solar panel of the invention comprises moreover a watertight electrical connector 11 allowing the panel to be electrically connected to a static converter external to the panel as explained hereinafter. Such a watertight connector has for example an IP68 level of protection according to international classification. In the example shown, the watertight connector 11 emerges onto a short side of the chassis 4, typically in the centre, within the thickness of the edge of the panel 1. In a variant, the connector can also emerge onto a long side of the panel. In yet another variant, it can be incorporated into the securing mechanism of the panel.

Further embodiments are described hereinafter only insofar as they differ from the preceding embodiment. Means that are similar in their structure or function to those previously described have numerical references that are identical or increased by one hundred with respect to the preceding disclosure.

FIG. 4 represents a further embodiment of a panel 101 according to the invention, in which the buoyant structure comprises a chassis 104 having the general shape of a rectangular frame in a top view. The chassis 104 is constituted by four quarter-circle or quarter-cylinder corners 105 connected in twos by profiles 106 having a U-shaped transverse cross-section, the opening of the U being turned towards the centre of the panel 101 while the central portion joining the two arms of the U is turned towards the outside of the panel 101. Preferably, the central portion of the U turned outwards has a rounded shape or at least rounded corners having a smooth appearance, similar to the rounded quarter-circle or quarter-cylinder corners 105.

The chassis 104 in FIG. 4 comprises an inner rim (not shown) or a retaining peripheral support surface for the stacked elements similar to those previously described (support plate, buoyancy means having the form of a buoyant slab, solar module 103). The

chassis constitutes a structural element replacing in this instance the chassis 4 of the panel in FIGS. 1 to 3.

The chassis 104 constitutes moreover a peripheral shock absorbing fender allowing the contact between panels or with any foreign object to be damped. It thus protects the photovoltaic cell module 103 from any damage. It is noted that the peripheral fender can be formed over the entire periphery of the panel. In a variant embodiment, the fender can be localized in some peripheral areas only, for example at the outer corners of the panel.

Optionally, such a chassis 104 can additionally provide a buoyancy function, capable of use instead of, or as well as, the buoyancy means situated below the upper face of the panel 101. To this end, the chassis 104 can be constituted by hermetically sealed profiles 106 (on the open side of the U) or covered with a buoyant material (not shown). The buoyant structure as a whole is adapted, as previously, to float with the upper face of the panel flush with the water level (theoretical position in calm water).

The panel 101 is here also equipped with an IP68-level watertight connector 111 emerging onto the outside of the chassis 104.

Attachment means 110, constituted in the case in point by pins inserted in each of the corners 105 of the panel 101, allow several panels 101 of the same type to be secured together or anchored on a fixed point by means of a system similar to the one mentioned previously (cables, cords, straps, rigid rods/link rods).

According to a further embodiment shown in FIGS. 6 and 7, the buoyant structure of the panel 201 comprises a chassis 204 having an outer form similar to the chassis 104 in FIG. 4, and is reinforced by an inner frame 204′ comparable to the frame 6 in FIGS. 1 to 3. The mechanical strength is provided both by the inner frame 204′ and by the chassis 204. Stacked elements are inserted in the buoyant structure (FIG. 7), from bottom to top: a support plate 208, buoyancy means 209 also contributing to the rigidity of the panel, a photovoltaic cell module 3.

The stacked elements are held by a lower rim or bearing surface 207 provided at the base of the inner frame 204′ or at the base of the chassis 204, the rim in this instance projecting towards the inside of the panel 201 below the inner frame 204′ (non shown).

The chassis 204 comprises a peripheral fender similar to 104 in FIGS. 4 and 5, extending over the entire periphery of the panel or situated in localized areas only.

The panel 201 is also equipped with an IP68-level watertight connector (not shown) emerging onto the outside of the chassis 204.

The panel 201 also comprises attachment means 210, which can be similar to those already mentioned, or in a variant as shown in FIGS. 6 and 7, elements protruding with respect to the upper face of the panel 201. In this example, each element has the form of a horizontal bar connected to the upper face of the chassis and held at a distance therefrom by means of one or two vertical pins. There are four of said protruding elements, substantially situated at the four corners of the chassis 204. They allow several panels 201 of the same type to be secured together or made fast on a fixed point by means of a system of cables or cords.

A further embodiment is also shown in FIGS. 8 and 9. The panel 301 comprises a buoyant structure similar to the panel in FIGS. 1 to 3. Unlike in the previous instance, the solar module 303 is here provided with a solar concentrator or is arranged so as to optimize the output of the photovoltaic cells 302. In a non-exhaustive example of the arrangement of the photovoltaic cells inside a solar module, the cells 302 can be covered with polarizing means (not shown) or be arranged for example non-horizontally (for example vertically). In the latter instance, solar radiation reflection means 312, constituted by concave reflective surfaces, are arranged in the solar module 303. These concave surfaces can be for example shaped semi-cylindrically, juxtaposed in

a generally planar form. The concave portions receiving the cells 302 are turned upwards. A transparent wall 313 covers the reflection means 312. End plates also close the ends of the semi-cylinders so as to form with the reflection means 312 a hermetically sealed watertight housing. The end plates are for example formed of the short sides or the long sides of the chassis 304 in the form of a frame (short sides in the example shown). Provision can be made for the panel 301 to be constituted by the following stacked elements: support plate, buoyancy means, solar module (from bottom to top). In a variant, provision can be made for the solar module 303 itself to provide the buoyancy of the panel as a result of the volume of air that it encloses in a watertight manner. In the latter instance, the support plate and/or the buoyancy means can be dispensed with. The element 314 within which the reflection means 312 are formed is in this instance structural and contributes to the stiffness of the buoyant structure when combined with the chassis 304 in the form of a frame. The hollow and protruding forms act in a similar manner to stiffening ribs and oppose in particular the bending and twisting of the panel.

The panel 301 is here also equipped with an IP68-level watertight connector 311 emerging onto the outside of the chassis 304.

Attachment means 310, constituted by rings connected to each of the corners of the panel 301, allow several panels 301 of the same type to be secured together or made fast to a fixed point by means of a system similar to the one mentioned previously (cables, cords, straps, rigid rods/link rods). The buoyant structure constituted is adapted for the panel to float such that the upper face of the panel 301 is flush with the water level (theoretical position in calm water).

FIGS. 10 and 11 show a further embodiment of the solar panel 401 according to the invention, in which the solar module 403 is incorporated into a buoyant structure arranged above the photovoltaic cells 402 or entirely covering them. The buoyant structure comprises a flexible or rigid pneumatic envelope 415 closed on itself in a watertight manner. The latter is for example made of

polymer. The envelope has a generally rectangular shape in top view, the peripheral edges coinciding substantially with those of the solar module 403 comprising the photovoltaic cells 402. The envelope 415 comprises an upper wall 416 that is transparent or translucent or at least permeable to solar radiation. The side walls 417 can also be permeable to solar radiation. The envelope has an upper portion having at the centre a slightly domed or substantially planar shape, the peripheral portions also being rounded around the peripheral edges of the solar module 403. The buoyant structure is structural in this instance and provides the stiffness of the assembly. The solar power collecting means, in the case in point the photovoltaic cells, are situated inside and at the base of the envelope 415. As shown in this example, the upper face on which the photovoltaic cells are arranged is not necessarily a face situated at the top of the panel, but a face turned upwards.

FIG. 12 shows a further embodiment of a panel 501 according to the invention. The latter comprises a buoyant structure constituted by a pneumatic envelope 515 as in the previous instance. The structure comprises moreover a support plate 518 on which the solar module 503 is arranged, the cells being situated on an upper face, i.e. turned upwards. The envelope can be closed on itself in a watertight manner, or can be connected in a watertight manner to a peripheral area of the support plate 518, around the solar module 503. The support plate 518 contributes to the stiffness of the assembly (opposing bending, bending or warping).

The panel 411 is also equipped with an IP68-level sealed connector 411 emerging onto the outside of the carrying structure, for example below the solar module 403 or the support plate 518.

In the examples in FIGS. 10 to 12, attachment means 410 for example constituted by securing rings can be provided at the four corners of the panel 401 in order to connect together several panels of the same type or to connect them to a fixed point, by means of a system similar to that previously mentioned (cables, cords, straps, rigid rods/link rods).

The buoyant structure constituted is adapted for the panel to float such that the upper wall 416, 516 of the envelope 415, 515 is flush with the water level (theoretical position in calm water).

FIGS. 13 and 14 represent yet a further embodiment of a panel 601 according to the invention. The panel comprises a buoyant structure constituted by a pneumatic sponson (or float) 615 having the general shape of a rectangular frame. Its arms have for example a substantially circular transverse cross-section. The sponson 615 is situated on the periphery of the panel 601. The solar module 603 incorporating the cells 602 is mounted on a support plate 618 having a generally rectangular shape corresponding substantially to the shape of the solar module. The support plate 618 is mounted and fixed on its periphery on an upper area of the pneumatic sponson 615.

The buoyant structure constituted by the adjacent support plate 618 and the pneumatic sponson 615 is stiff and resistant to the effects of bending, twisting or warping.

The panel 601 is equipped with an IP68-level sealed connector 611 emerging onto the outside of the buoyant structure, for example below the support plate 618.

Attachment means 610 constituted by securing rings are provided at the four corners of the panel 601 in order to connect together several panels of the same type or to connect them to a fixed point, by means of a system similar to that previously mentioned (cables, cords, straps, rigid rods/link rods).

The buoyant structure is adapted for the panel 601 to float such that the upper face is flush with the water level (theoretical position in calm water).

FIG. 15 represents yet a further embodiment of the panel 701 according to the invention, wherein the buoyant structure is constituted by a solar module 703 having photovoltaic cells 702 and a support plate 718 of the same type as those in FIGS. 13 and 14.

The solar module 703 is here mounted on “natural” buoyancy means 715 of the bamboo cane or wood log type or other equivalent elements having a low environmental impact, such as recycled plastic bottles. In the example shown in FIG. 15, the structure is constituted by two superimposed layers of bamboo rods or logs juxtaposed in parallel in each layer, the bamboo canes of the two adjacent layers being perpendicular to each other. It is understood that any configuration comprising at least two layers of bamboo rods or logs falls within the scope of the invention. It is perfectly possible to envisage an arrangement of three layers or even more. As in the embodiments previously described, the panel 701 is equipped with an IP68-level watertight connector 711 emerging onto the periphery of the buoyant structure, for example below the support plate 718.

Attachment means 710 constituted by securing rings are provided at the four corners of the panel 701 to connect together several panels of the same type or to connect them to a fixed point, by means of a similar system to the one previously described (cables, cords, straps, rigid rods/link rods).

The buoyant structure is adapted for the panel 701 to float such that the upper face is flush with the water level (theoretical position in calm water).

Each panel 1-701 of the invention previously described constitutes a basic component of a larger power plant that is also a subject of the present invention. This power plant constitutes a “field” or “set” of solar panels 1-701 such as those previously described, which are individually buoyant when installed, the panels being juxtaposed and secured together by systems of cables or cords to form a net. This net can have a generally rectangular or square shape in top view, as shown in FIG. 16.

Without exceeding the scope of the invention, the net can have other geometrical shapes in top view, for example circular, hexagonal or other.

FIG. 16 represents in top view an example of such a power plant comprising a net having the appearance of a matrix: in fact

in this example the solar panels 1-701 are aligned with each other in rows and columns.

The example represents 240 solar panels 1-701 aligned in 20 columns each of 12 panels. In this example it is assumed that the rectangular panels 1-701 have dimensions of 1.56 m×0.93 m, and that a gap d of the order of 0.30 m is made between each panel (in this instance, between two adjacent rows and between two adjacent columns). Other panel dimensions can be envisaged. The connection and said gap between the panels are provided by a system of cords or cables. It is noted that such a gap between the panels advantageously provides for the passage of light between the panels, allowing good conditions for photosynthesis on the sea bed to be maintained and avoiding disturbance to the environment for flora and/or fauna. In some situations, it is appropriate to avoid the power plant forming a screen with large dimensions which would be harmful to the environment. The net of panels 1-701 is held on the periphery and/or subjected to outward peripheral traction, under the effect of peripheral retaining means 20, 21. These include buoys 20 situated around the net of panels 1-701. In the example described, four buoys 20 situated at the four corners of a rectangle or square are connected together in twos by four linkages 21 constituted by substantially tensioned cables or cords or straps. In a variant embodiment, said linkages can be constituted by rigid rods which moreover can contain the electrical connection or pneumatic elements or connecting links with the panels. The linkages 21 produce a rectangular or square form of the power plant. The buoys are immobilized as will become apparent hereinafter. The distance D between each panel situated on the outside of the net and the adjacent linkage is approximately 1.5 m (non-limitatively, by way of illustration only). The set of panels connected to each other is attached on the periphery to the linkages 21 by means of cords or cables or straps or rigid peripheral link rods 22. Given the aforementioned dimensions, in this example, a field (or net) of solar panels 1-701 is obtained having dimensions of the order of 30.31 m by 28 m (L×H), i.e. roughly square in shape.

According to a particular embodiment of a power plant according to the invention, the panels 1-107 are secured directly to each other by means of a system of cords or cables or straps 23 connecting their chassis or their fenders. The structure of each panel by itself provides for the take-up of stresses, essentially tensile forces in the general plane of the set of panels 1-107. FIG. 17 represents an example of this type of power plant, the panel 107 shown being of a particular type previously described, on the understanding that other types of panels falling within the scope of the invention can be also used, in particular panels referenced 1, 201-701. In this example, four panels 107 arranged in a square are connected diagonally in twos by a set of two cords 23 crossing at their centre. The cords 23 can be free or joined at their crossing point.

On the periphery, the panels are also connected to the linkages by cords or cables or connecting straps 22.

Moreover, conducting cables 24 electrically connect the panels 1-107 to an external static converter. To this end, the panels 1-107 can be connected to an external cable or to a common network by means of their single connector 11-711 or by means of two connectors provided on each panel, the panels being in the latter instance provided with integrated electrically conducting means and capable of being arranged in series (which limits the routing of the electricity cables on the outside of the panels and thus ensures better protection of said cables).

With reference to FIG. 18, one corner of the solar panel power plant 101 is shown. As is apparent in this example, inner linkages 25 can be provided to supplement the linkages 21 connecting the buoys situated at the corners of the power plant. These inner linkages are for example situated between each column and each row or line of solar panels 101, so as to also form a net or a matrix. The panels 101 are connected or secured to said net or to said common matrix of cables or cords or straps by means of their buoyant structure, in particular their chassis or by means of their fenders. Said inner linkages 25 provide the mechanical strength of the power plant assembly, by withstanding all or some of the tensile stresses

applied to the panels towards the outside of the power plant (through the retaining means and also by the effect of the swell). The mechanical stresses applied to the panels 101 are thus considerably reduced, making it possible to have only the necessary dimensions and therefore a reduced cost of the panels.

It is noted with reference to FIGS. 18 and 19 that the conducting cables electrically connected to the solar panels 101 are also connected to a static converter (not shown) advantageously housed in one of the buoys 20 of the power plant. The buoy is thus equipped with a watertight opening system (not shown) and comprises a fully watertight enclosure protected from external attack. In a variant of the invention (not shown), the static converter can be situated in another enclosure close to the power plant or remotely. An electrical connection is also provided between the convertor and a power plant or a remote electricity network.

FIGS. 20 to 22 represent in perspective view and at different angles a further embodiment of the power plant of panels 101 according to the invention.

This embodiment is very close to that in FIG. 18, with the only difference being that floats 26 are provided on the net or matrix of cords, cables or straps (inner linkages 25), as well as on the outer linkages 21 of the retaining means.

The floats 26 are distributed over the entire length of the linkages 21, 25 and are spaced apart in twos by approximately 0.5 m to 1 m (other arrangements are possible). Thus the net (or matrix) is itself buoyant. The buoyancy means incorporated into the panels can be retained as explained in the examples previously described or can optionally be made lighter or reduced or even dispensed with in order to simplify the structure of the panels and reduce their production cost.

In this example, FIGS. 21 and 22 represent the electrical connection between the different panels and the static converter, provided by conducting cables 27 routed along the inner linkages 25.

The buoys 20 are immobilized by a system of submerged weights 28 (dead weights) situated approximately 15 to 30 m, for example 20m, below the buoy 20 and resting on the bed 29 of the body of water. The invention is thus applicable in particular to marine environments or other aquatic environments having a water depth of approximately 15-30 m. Further embodiments can also be envisaged within the scope of the invention. The connection between the buoys 20 and the weights can be provided by a chain 30, a cable or any other equivalent means. In the non-limitative example in FIG. 23 three weights 28 of 5 tonnes each are provided.

In the event of installation in a marine environment, compensation means for the height h of the set of panels 1-107 with respect to the sea bed 29 are provided in order to adapt continuously and automatically to the tides (for example an adequate length of chain connecting each buoy 20 to the submerged weights 28).

Solar panels having photovoltaic cells have been described above. The invention can be applied similarly to solar thermal panels (heat exchanger/heat pump; this embodiment is not shown). Such a panel according to the invention comprises means of heat exchange combined with a buoyant structure. The panel thus constituted can be made fast to further panels in a manner comparable to that described for solar photovoltaic panels. Ducts can be tilted in order to ensure satisfactory operation of the device. Pipes connect the panels to an external device using or treating the water heated by the solar panels.

In a variant, the power plant can be constituted by of a mix of solar photovoltaic panels and solar thermal panels.

In the event of moving the solar power plant on the surface of the water, the linkages can be provided, optionally in a temporary and detachable manner, with means that are rigid under tension/compression, for example rigid rods or braces (connecting the buoys), ensuring that the power plant retains its general shape and that the panels do not knock together, releasing the anchoring of the buoys.

In a variant embodiment of the invention, rigid buoys having longitudinal shapes can be provided and installed on the sides of the polygon, for example on the four sides of the rectangle formed by the solar panel power plant. These rigid buoys are connected in twos at their ends and keep the general shape of the peripheral part of the power plant. They also facilitate the operations of moving the power plant.

It has also been stated that each solar panel according to the invention has a substantially constant thickness in a direction perpendicular to the upper face of the panel. This configuration can be permanent using a non-modifiable or convertible panel. On the other hand, in a variant embodiment (not shown) of the invention, the solar panel according to the invention is capable of being converted between a first configuration in which the panel effectively has a substantially constant thickness in a direction perpendicular to the upper face of the panel, and a second configuration in which the thickness is not constant, the upper face of the panel being in the latter instance inclined with respect to the horizontal, for example for increased exposure to light or to solar radiation.

Of course, the invention is not limited to the means that have just been described and comprises all the technical equivalents.

1. A solar panel comprising: solar power collecting means, such as solar collectors or photovoltaic cells; the panel also having an upper face; a unitary buoyant structure on which the solar power collecting means are mounted, the latter being incorporated into a solar module arranged, in particular flat, on the buoyant structure; and the panel having, in a direction perpendicular to the upper face, a substantially constant thickness at least in a peripheral region of the panel.

2. The solar panel according to claim 1, characterized in that the solar power collecting means are constituted by photovoltaic cells.

3. The solar panel according to claim 1, characterized in that the buoyant structure is shaped to position the upper face substantially horizontally.

4. The solar panel according to claim 3, characterized in that the buoyant structure is adapted to position the upper face substantially flush with the level of the surrounding liquid, in particular seawater or fresh water.

5. The solar panel according to claim 1, characterized by having in a top view the general shape of a parallelogram and a surface area less than 4 m², in particular comprised between 1 and 2 m².

6. The solar panel according to claim 1, characterized in that the buoyancy means are uniformly distributed below the upper face.

7. The solar panel according to claim 1, characterized in that the buoyancy means are distributed on the periphery of the upper face.

8. The solar panel according to claim 1, characterized in that the buoyant structure comprises a chassis in which are stacked, from bottom to top, at least one support plate, in particular made of fibreglass, at least one buoyant slab, in particular made of polymer, and a layer of solar power collecting means.

9. The solar panel according to claim 1, comprising shock absorbing fenders situated on the periphery of the panel, these fenders being in particular buoyant and made of polyurethane.

10. The solar panel according to claim 1, comprising attachment means allowing several solar panels of the same type to be secured together.

11. The panel according to claim 2, comprising at least one watertight electrical connector, allowing the photovoltaic cells to be electrically connected.

12. A solar power plant comprising an assembly of several solar panels according to claim 1, the individually buoyant panels being juxtaposed forming a net, having in particular the general shape of a square or rectangle.

13. The solar power plant according to claim 12, characterized in that the panels are secured directly to each other by means of a system of cords, cables or straps connecting their chassis or support plate, or their fenders.

14. The solar power plant according to claim 13, characterized in that the panels are secured on a common net of cables, cords or straps, by means of their chassis or support plate or their fenders.

15. The solar power plant according to claim 12, comprising peripheral retaining means situated around the set of solar panels so as to immobilize it with a substantially flat arrangement of the juxtaposed panels.

16. The solar power plant according to claim 15, characterized in that the peripheral retaining means are constituted by several flotation buoys immobilized by a system of submerged weights, in particular four flotation buoys situated at the four corners of a set of solar panels having a generally square or rectangular shape.

17. The solar power plant according to claim 15, characterized in that at least one peripheral retaining means incorporates a static converter for the conversion of the electricity arriving from the solar panels of photovoltaic type by suitable conducting means, said converter conveying the electricity to an electricity network remote from the solar power plant.
